(19) United States
(12) Patent Application Publication
(10) Pub. No.: US 2020/0066640 A1
(43) Pub. Date: Feb. 27, 2020

(54) HYBRID TECHNOLOGY 3-D DIE STACKING

(71) Applicant: Intel Corporation, Santa Clara, CA (US)

(72) Inventors: Arnab SARKAR, Chandler, AZ (US); Ravindranath V. MAHAJAN, Chandler, AZ (US)

(21) Appl. No.: 15/774,512

(22) PCT Filed: Dec. 26, 2015
(86) PCT No.: PCT/US2015/000383

§ 371 Date: May 8, 2018

(51) Int. Cl. H01L 23/538; H01L 25/065; H01L 23/31; H01L 23/00

(52) U.S. Cl. CPC H01L 23/5384; H01L 25/0657; H01L 23/5385; H01L 2225/06513; H01L 23/3128; H01L 24/97; H01L 23/5386

(57) ABSTRACT

Embodiments are generally directed to hybrid technology 3-D die stacking. An embodiment of an apparatus includes a TSV array substrate including through silicon vias (TSVs) and wire bond contacts; a stack of one or more wire bond dies; and a package coupled with the TSV substrate by a first interconnect, wherein the one or more wire bond dies are connected via one or more wires to one or more wire bond contacts of the TSV array substrate, and wherein the TSV array substrate provides connections to the for each of the one or more wire bond dies.

### TECHNICAL FIELD

Embodiments described herein generally relate to the field of electronic devices and, more particularly, to hybrid technology 3-D die stacking.

### BACKGROUND

In the fabrication of electronic apparatuses, the stacking of multiple dies has become popular because of advantages in reducing the physical space of a device, together with the advantage of reduced distance between components.

However, the combination of different types of dies in an apparatus can require some complexity and expense in fabrication, and may result in a product that is undesirably large.

For example, the combination of wire bond technology dies and flip chip technology dies requires the use of a separate packages, with the packages then being stacked in a package on package fashion. The resulting product thus requires a significant number of components and interconnections, and further results in an inflexible design that is only useful if a particular design will require both wire bond and flip chip dies.

### BRIEF DESCRIPTION OF THE DRAWINGS

Embodiments described here are illustrated by way of example, and not by way of limitation, in the figures of the accompanying drawings in which like reference numerals refer to similar elements.

FIG. 1 is an illustration of a hybrid flip chip and wire bond apparatus according to an embodiment;

FIG. 2 is an illustration of package on package apparatus including flip chip and wire bond connections;

FIG. 3 is an illustration of a hybrid flip chip and wire bond apparatus according to an embodiment;

FIG. 4 is an illustration of a wire bond stack apparatus according to an embodiment;

FIG. 5 is an illustration of flip chip and wire bond apparatus according to an embodiment;

FIG. 6 illustrates a process flow for the fabrication of a hybrid die apparatus; and

FIG. 7 is an illustration of a mobile device including a hybrid die apparatus according to an embodiment.

### DETAILED DESCRIPTION

Embodiments described herein are generally directed to hybrid technology 3-D die stacking.

For the purposes of this description:

“Mobile electronic device” or “mobile device” refers to a smartphone, smartwatch, tablet computer, notebook or laptop computer, handheld computer, mobile Internet device, wearable technology, or other mobile electronic device that includes processing capability.

“Flip chip” or “flip chip device” refers to a semiconductor device including contacts (which may specifically be micro bump contacts) on a top side of a wafer, wherein the contacts allow for the device to be flipped over (inverted) such that the top side faces down to align with and attach with contacts of another element, such as a wafer or substrate, where the attachment may include solder being reflowed to complete the interconnect.

“Wire bonding” refers to a process of mounting a wire bond chip in an upright (non-inverted) arrangement and utilizing wires to interconnect chip pads of the wire bond chip to another element, such as to wire bond contacts on a wafer or substrate.

“Package on Package” or “PoP” refers to integrated circuit packaging by which multiple packages may be interconnected in a vertical stack.

“Through silicon via” or “TSV” refers to a vertical (perpendicular to a surface) electrical connection (or via) that passes through a silicon wafer or substrate.

“Substrate” or “wafer” refers to a slice of a substance, including a slice of semiconductor material, such as silicon, used in electronics for the fabrication of integrated circuits and in photovoltaics for wafer-based solar cells.

In some embodiments, an apparatus, system, or process utilizes hybrid technology 3-D die stacking for a device including wire bond connections for one or more dies in a stack, wherein connections for one or more dies are provide through a full or partial grid

TSV (through silicon via) array substrate. In some embodiments, an apparatus, system, or process provides for a hybrid device including both wire bond connections for the one or more dies in a stack and further includes flip chip bond pads for a bottom die in a stack, wherein connections are enabled for both through a full or partial grid TSV (through silicon via) array substrate.

As used here, a full grid TSV array substrate refers a substrate in which an array of TSVs is provided through all or most of the substrate, while a partial grid array substrate regards a substrate in which an array of TSVs is provided through a portion of the substrate. In some embodiments, connections for an apparatus are a hybrid combination of flip chip connections for a flip chip die, the flip chip die being a bottom die in a stack, and wire bond connections for one or more dies stacked on top of the bottom die. TSVs may be utilized to connect devices or circuitry, wherein the TSVs interconnect metal layers in a front side of the silicon to pads or micro bumps on a back side of the silicon, enabling a set of interconnects on the backside of the silicon. The set of interconnects on the backside of the silicon are commonly implemented with an additional routing/redistribution layer on the backside of the silicon.

In some embodiments, an apparatus, system, or process enables wire bond connection on a full or partial grid TSV array substrate. In some embodiments, an apparatus, system, or process enables both wire bond and flip chip bond pads (on the back side of a bottom die in the stack) through a full or partial grid TSV array substrate covering all or a portion of the substrate.

In some embodiments, the wire bond pads have an Al (aluminum) based surface finish (such as Ti(Titanium)Al(Aluminum)) or other surface finish to enable wire bonding. In this manner, subsequent dies of both flip chip or wire bond types can be stacked and directly connected to the bottom die.

In some embodiments, an apparatus, system, or process eliminates the necessity for a separate package for wire bond dies, and thus eliminates the need for a bottom package to include package on package pads. Further, a bottom die in the die stack can directly communicate with the other die without going through a package, thus improving both cost and performance. In some embodiments, an apparatus, system, or process eliminates the need for a top package in a stack die apparatus, thereby simplifying fabrication and reducing costs in the generation of electronic devices.

In some embodiments, an apparatus, system, or process includes a layer for wire bond connection, allowing for the different coupling processes for flip chip and wire bond connections. In some embodiments, the apparatus is to enable both wire bond and flip chip bond pads for connection via the TSV array substrate.

In some embodiments, an apparatus is not limited to any particular number of dies, but rather can include multiple wire bond dies in a stack, wherein the stack may be further stacked with a flip chip die. In some embodiments, a hybrid flip chip and wire bond apparatus may assist in reducing the z-height of a package, in addition to reducing cost and difficulty of fabrication with the elimination of the top package in the stacked device.

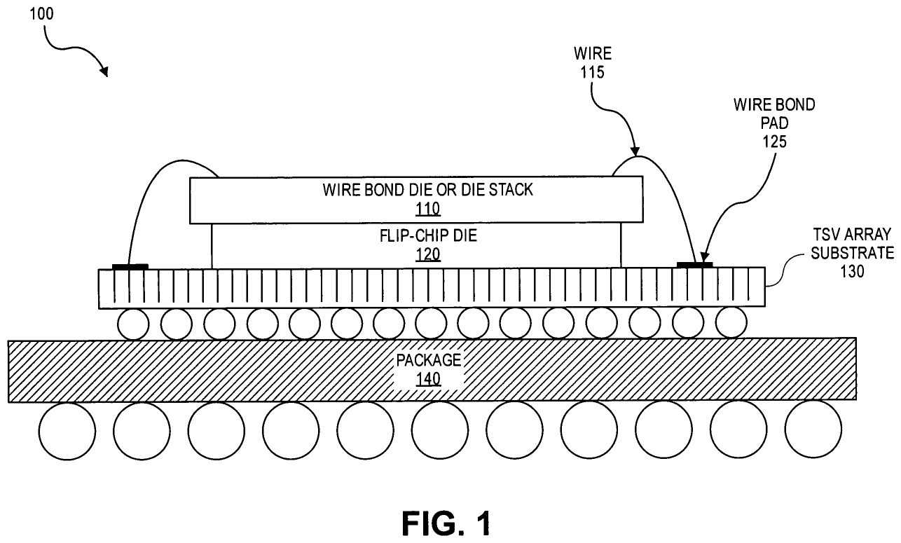

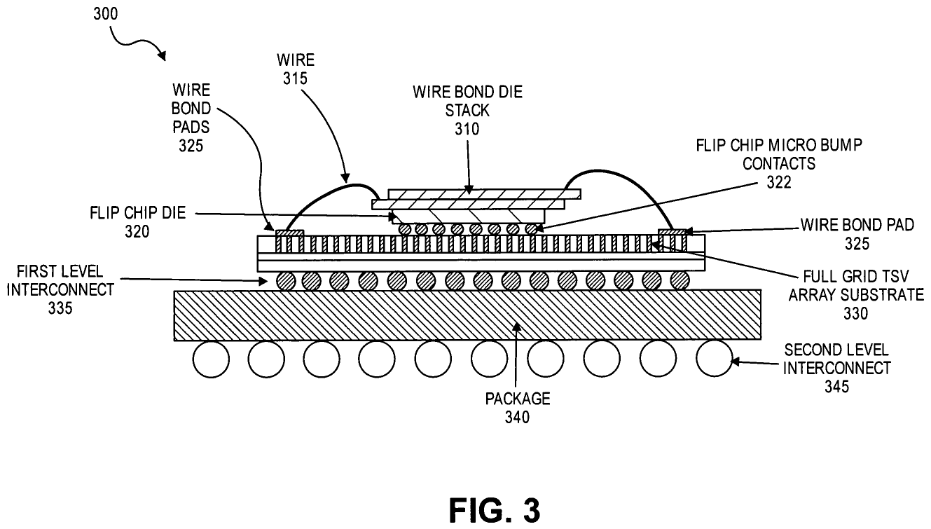

FIG. 1 is an illustration of a hybrid flip chip and wire bond apparatus according to an embodiment. Further details and variations are illustrated in FIGS. 3 through 5.

In some embodiments, as apparatus 100 includes a wire bond die or a wire bond die stack including multiple wire bond dies 110. In some embodiments, the wire bond die or wire bond die stack 110 is coupled with a through silicon via grid 130. In other embodiments, the wire bond die or wire bond die stack 110 is coupled with a first side of a flip chip die 120. In some embodiments, the flip chip die 120 is flipped (inverted) such that a former top side (the second side) of the inverted flip chip die 120 is coupled with a first set of TSVs of the TSV array substrate 130, and the wire bond die or die stack 110 is coupled with the original bottom side (the first side) of the inverted flip chip die 120.

In some embodiments, a set of wire bond pads 125 are connected to the TSV grid 130, wherein the wire bond die or die stack 110 are connected to the wire bond pads 125 by one or more wires 115.

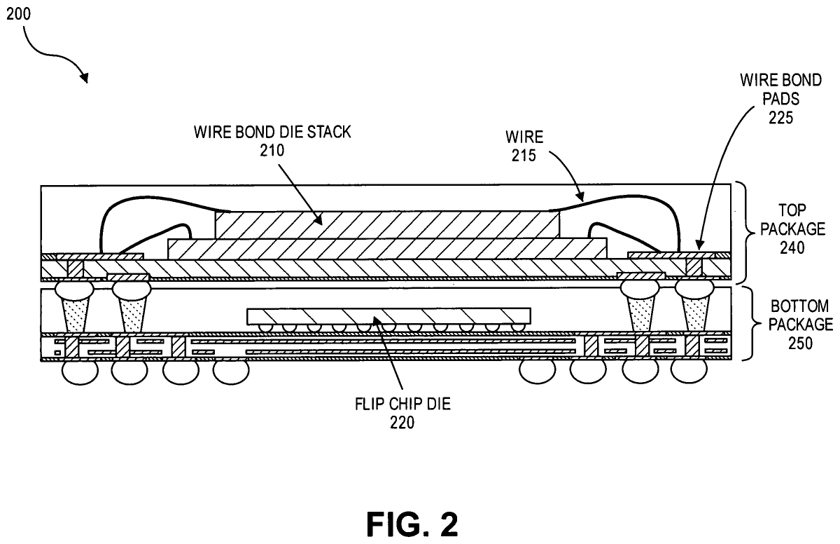

FIG. 2 is an illustration of package on package apparatus including flip chip and wire bond connections. In a conventional package on package apparatus 200, the apparatus includes a top package 240 and a bottom package 250. As illustrated, the first package includes a wire bond die stack 210 that is connected to wire bond pads 225 of the first package 240 via wires 215. Further, the second package 250 includes a flip chip die 220, the flip chip die 220 being flipped such that the inverted flip chip is connected with contacts of the second package 250.

As illustrated, in conventional package on package technology, a combined arrangement of flip chip and wire bond stacked die products requires separate packages for the wire bond die and the flip chip die, with connections between the wire bond die and the flip chip die being made through package on package metal layer on the bottom package 250. The apparatus 200 requires complex interconnection between the die, and further requires additional height to accommodate the two packages.

FIG. 3 is an illustration of a hybrid flip chip and wire bond apparatus according to an embodiment. In some embodiments, as apparatus 300 includes a wire bond die stack (including a stack of wire bond dies) 310 coupled with a first side of flip chip die 320. In some embodiments, the flip chip die 320 is flipped such that a top side (the second side) is flipped down and coupled with a first set of TSVs of the TSV array substrate 330 by a set of flip chip micro bump contacts 322. In this implementation, the TSV array substrate is a full grid TSV array substrate. In some embodiments, the wire bond stack 320 is coupled with the original bottom side (the first side) of the inverted flip chip die 310.

In some embodiments, a set of wire bond pads 325 are connected to the TSV grid 330, wherein each die of the wire bond die stack 310 is connected to certain of the wire bond pads 325 by one or more wires 315.

In some embodiments, the TSV array substrate 330 is connected with a single package 340 by a first level interconnect 335 that provides connectivity for each of the wire bond dies 310 and the flip chip die 320, with the package further including a second level interconnect 345 for the connection of the apparatus 300 in a system.

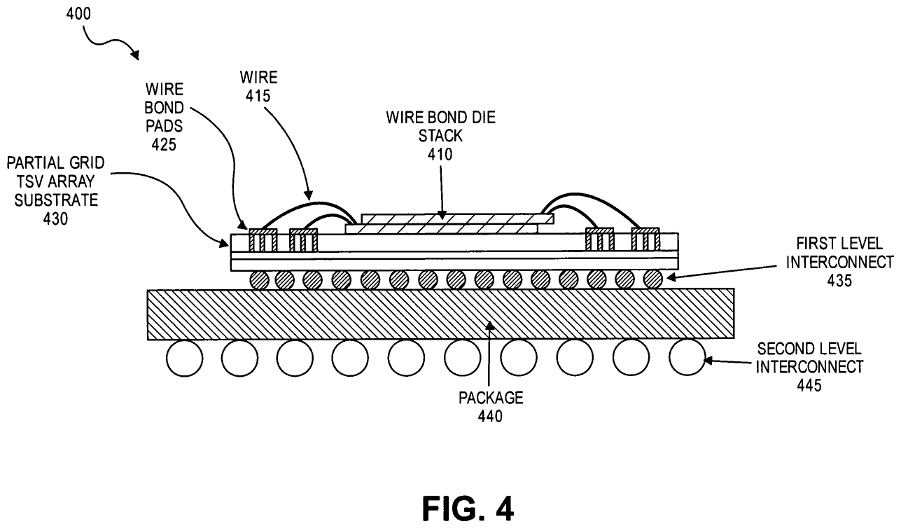

FIG. 4 is an illustration of a wire bond stack apparatus according to an embodiment. In some embodiments, as apparatus 400 includes a wire bond die stack (including a stack of wire bond dies) 410 coupled with a partial grid TSV array substrate 430. In some embodiments, the TSV array substrate 430 includes multiple wire bond contact pads 425. In some embodiments, a set of wire bond pads 425 are connected to the TSV grid 430, wherein each die of the wire bond die stack 410 is connected to certain of the wire bond contact pads 425 by one or more wires 415. While not illustrated in FIG. 4, the apparatus 400 may further include one or more flip chip dies that are connected to the TSV array substrate 430 in the same manner as the connection of flip chip 320 to TSV array 330 substrate as illustrated in FIG. 3. In addition, although this is not illustrated in FIG. 4, the wire bond contact pads 425 further require metal routing on the other side of the TSV substrate in order to connect to the TSVs.

In some embodiments, the TSV array substrate 430 is connected with a single package 440 by a first level interconnect 435 that provides connectivity for each of the wire bond dies 410, with the package 440 further including a second level interconnect 445 for connection of the apparatus 400 in a system.

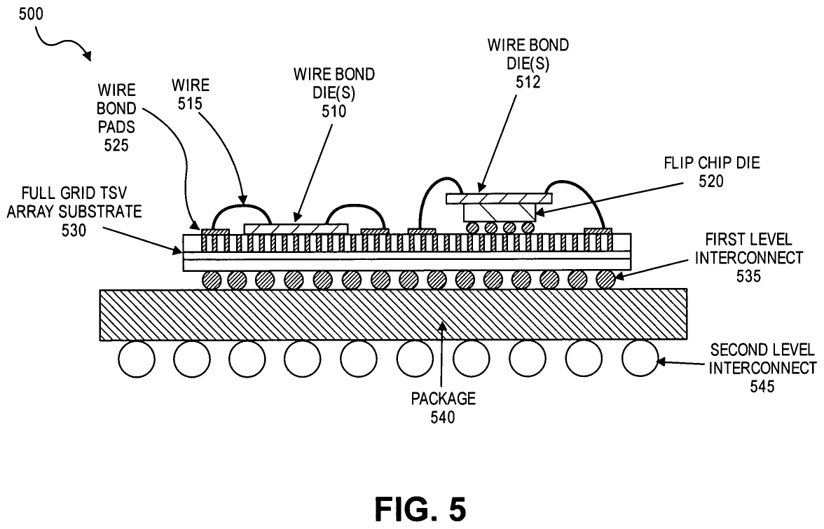

FIG. 5 is an illustration of flip chip and wire bond apparatus according to an embodiment. In some embodiments, as apparatus 500 includes a first wire bond die stack including one or more wire bond dies 510 and a second wire bond die stack including one or more wire bond dies 512 coupled with a first side of flip chip die 520. In some embodiments, the flip chip die 520 is flipped such that a top side (the second side) is flipped and coupled with a first set of TSVs of the TSV array substrate 530 by a set of flip chip micro bump contacts. In this implementation, the TSV array substrate 530 is a full grid TSV array substrate. In some embodiments, the first stack of wire bond dies 510 are coupled with the TSV array substrate 530 and the second set of wire bond dies 512 are coupled with the original bottom side (the first side) of the inverted flip chip die 520.

In some embodiments, a set of wire bond pads 525 are connected to the TSV grid 530, wherein each die of the first and second wire bond die stacks 510-512 is connected to certain of the wire bond pads 525 by one or more wires 515.

In some embodiments, the TSV array substrate 530 is connected with a single package 540 by a first level interconnect 535 that provides connectivity for each of the wire bond dies 510-512 and the flip chip die 520, with the package 550 further including a second level interconnect 545 for the connection of the apparatus 500 in a system.

It is noted that, while for ease of illustration the TSV Array substrate 530 is generally shown as a passive substrate (without active components such as transistors), embodiments are not limited to this illustration. In an actual implementation, the TSV substrate may include active transistors on a bottom (second or flipped) side, closer to first level interconnects 535.

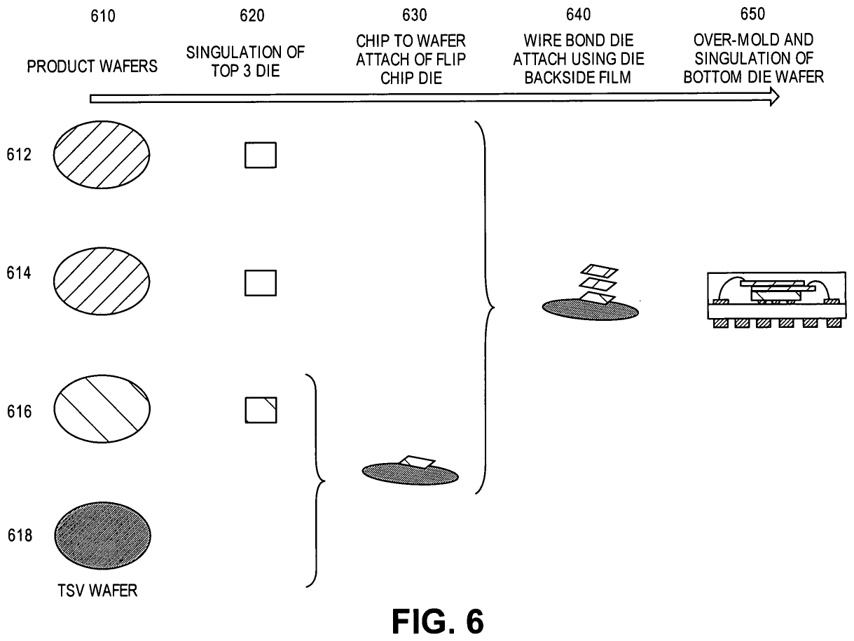

FIG. 6 illustrates a process flow for the fabrication of a hybrid die apparatus. In some embodiments, the process flow may include:

610: Wafer fabrication—Fabrication of the product wafers for the device, which in this instance includes wafers for wire bond dies 612-614, flip chip dies 616, and the TSV wafer 618.

620: Die singulation—Singulation of the wire bond and flip chip dies, excluding the bottom die wafer with the TSV array substrate.

630: Chip to Wafer Attachment—Chip to wafer attachment of the flip chip die to the bottom dies (TSV array substrate). The bottom die wafer containing the wire bond pads undergo an additional plating or surface finish step to deposit TiAl (or other material) to enable wire bonding, such as bonding on copper pads.

640: Attachment and Wire Bonding—Wire bond dies are attached in a stack using die backside films, and further are wire-bonded to the wire bond pads on the backside of the bottom die wafer.

650: Over-mold and Singulation—In some embodiments, the entire configuration is enclosed in a mold, and then a last process is to singulate the bottom wafer with the die stack into individual units. In some embodiments, the stacked molded die can then be attached to a package to obtain the configuration shown in, for example, FIG. 3.

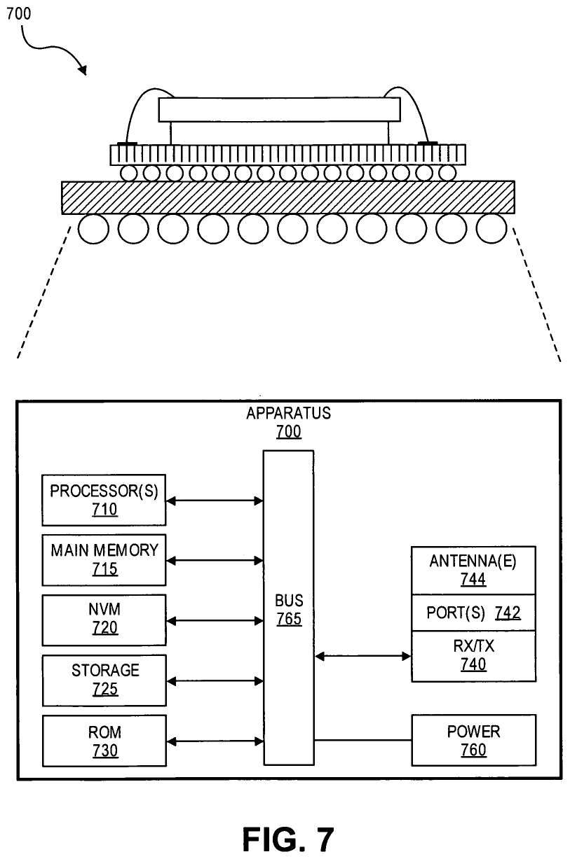

FIG. 7 is an illustration of a mobile device including a hybrid die apparatus according to an embodiment. In this illustration, certain standard and well-known components that are not germane to the present description are not shown. Elements shown as separate elements may be combined, including, for example, an SoC (System on Chip) combining multiple elements on a single chip.

In some embodiments, an apparatus 700 is fabricated as a hybrid die apparatus as illustrated in one or more of FIGS. 1-5.

In some embodiments, the apparatus 700 includes processing means such as one or more processors 710 coupled to one or more buses or interconnects, shown in general as bus 765. The processors 710 may comprise one or more physical processors and one or more logical processors. In some embodiments, the processors may include one or more general-purpose processors or special-processor processors. The bus 765 is a communication means for transmission of data. The bus 765 is illustrated as a single bus for simplicity, but may represent multiple different interconnects or buses and the component connections to such interconnects or buses may vary. The bus 765 shown in FIG. 7 is an abstraction that represents any one or more separate physical buses, point-to-point connections, or both connected by appropriate bridges, adapters, or controllers.

In some embodiments, the apparatus 700 further comprises a random access memory (RAM) or other dynamic storage device or element as a main memory 715 for storing information and instructions to be executed by the processors 710. Main memory 715 may include, but is not limited to, dynamic random access memory (DRAM).

The apparatus 700 also may comprise a non-volatile memory (NVM) 720; a storage device such as a solid state drive (SSD) 725; and a read only memory (ROM) 730 or other static storage device for storing static information and instructions for the processors 710.

In some embodiments, the apparatus 700 includes one or more transmitters or receivers 740 coupled to the bus 765 to provide wired or wireless communications. In some embodiments, the mobile device 705 may include one or more antennae 744, such as dipole or monopole antennae, for the transmission and reception of data via wireless communication using a wireless transmitter, receiver, or both, and one or more ports 742 for the transmission and reception of data via wired communications. Wireless communication includes, but is not limited to, Wi-Fi, Bluetooth™, near field communication, and other wireless communication standards.

The apparatus 700 may also comprise a battery or other power source 760, which may include a solar cell, a fuel cell, a charged capacitor, near field inductive coupling, or other system or device for providing or generating power in the apparatus 700. The power provided by the power source 760 may be distributed as required to elements of the apparatus 700.

In the description above, for the purposes of explanation, numerous specific details are set forth in order to provide a thorough understanding of the described embodiments. It will be apparent, however, to one skilled in the art that embodiments may be practiced without some of these specific details. In other instances, well-known structures and devices are shown in block diagram form. There may be intermediate structure between illustrated components. The components described or illustrated herein may have additional inputs or outputs that are not illustrated or described.

Various embodiments may include various processes. These processes may be performed by hardware components or may be embodied in computer program or machine-executable instructions, which may be used to cause a general-purpose or special-purpose processor or logic circuits programmed with the instructions to perform the processes. Alternatively, the processes may be performed by a combination of hardware and software.

Portions of various embodiments may be provided as a computer program product, which may include a computer-readable medium having stored thereon computer program instructions, which may be used to program a computer (or other electronic devices) for execution by one or more processors to perform a process according to certain embodiments. The computer-readable medium may include, but is not limited to, magnetic disks, optical disks, compact disk read-only memory (CD-ROM), and magneto-optical disks, read-only memory (ROM), random access memory (RAM), erasable programmable read-only memory (EPROM), electrically-erasable programmable read-only memory (EEPROM), magnet or optical cards, flash memory, or other type of computer-readable medium suitable for storing electronic instructions. Moreover, embodiments may also be downloaded as a computer program product, wherein the program may be transferred from a remote computer to a requesting computer.

Many of the methods are described in their most basic form, but processes can be added to or deleted from any of the methods and information can be added or subtracted from any of the described messages without departing from the basic scope of the present embodiments. It will be apparent to those skilled in the art that many further modifications and adaptations can be made. The particular embodiments are not provided to limit the concept but to illustrate it. The scope of the embodiments is not to be determined by the specific examples provided above but only by the claims below.

If it is said that an element “A” is coupled to or with element “B,” element A may be directly coupled to element B or be indirectly coupled through, for example, element C. When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification or claim refers to “a” or “an” element, this does not mean there is only one of the described elements.

An embodiment is an implementation or example. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments, various features are sometimes grouped together in a single embodiment, figure, or description thereof for the purpose of streamlining the disclosure and aiding in the understanding of one or more of the various novel aspects. This method of disclosure, however, is not to be interpreted as reflecting an intention that the claimed embodiments requires more features than are expressly recited in each claim. Rather, as the following claims reflect, novel aspects lie in less than all features of a single foregoing disclosed embodiment. Thus, the claims are hereby expressly incorporated into this description, with each claim standing on its own as a separate embodiment.

In some embodiments, an apparatus includes a TSV array substrate including through silicon vias (TSVs) and wire bond contacts; a stack of one or more wire bond dies; and a package, a first side of the package being coupled with the TSV array substrate by a first interconnect. In some embodiments, the one or more wire bond dies are connected via one or more wires to one or more wire bond contacts of the TSV array substrate; and the TSV array substrate provides connections for each of the one or more wire bond dies.

In some embodiments, the apparatus further includes at least a first flip chip die including flip chip contacts on a first side of the first die, the first flip chip die being flipped to couple the flip chip contacts with the TSV array substrate.

In some embodiments, the stack of one or more wire bond dies is coupled to a second side of the flip chip die.

In some embodiments, the TSV array substrate containing the wire bond pads includes deposited material to enable wire bonding on the wire bond pads.

In some embodiments, the deposited material includes TiAl (Titanium Aluminum).

In some embodiments, the apparatus further includes a second interconnect on a second side of the package.

In some embodiments, a mobile device includes a processor; a memory for storage of data for the processor; and a transmitter and receiver for the transfer of data together with one or more antennae for data transmission and reception. In some embodiments, one or more components of the mobile device are included in a die stack including: a TSV array substrate including through silicon vias (TSVs) and wire bond contacts, a stack of one or more wire bond dies, and a package, a first side of the package being coupled with the TSV array substrate by a first interconnect. In some embodiments, the one or more wire bond dies are connected via one or more wires to one or more wire bond contacts of the TSV array substrate; and wherein the TSV array substrate provides connections for each of the one or more wire bond dies.

In some embodiments, the die stack further includes at least a first flip chip die including flip chip contacts on a first side of the first die, the first flip chip die being flipped to couple the flip chip contacts with the TSV array substrate.

In some embodiments, the stack of one or more wire bond dies is coupled to a second side of the flip chip die.

In some embodiments, the TSV array substrate containing the wire bond pads includes deposited material to enable wire bonding on the wire bond pads.

In some embodiments, the deposited material includes TiAl (Titanium Aluminum).

In some embodiments, the die stack further includes a second interconnect on a second side of the package.

In some embodiments, a method includes fabricating a TSV array wafer including through silicon vias (TSVs); attaching a first flip chip die to a first side of the TSV array wafer using a chip to wafer attachment; and attaching multiple wire bond dies in a stack to the first flip chip die, and wire bonding the wire bond dies on wire bond pads to the TSV array wafer.

In some embodiments, the method further includes enclosing the dies in a mold and singulating a stacked molded die including the first flip-chip, the wire bond dies, and a TSV array substrate.

In some embodiments, the TSV array substrate includes a first level interconnect on a second side of the TSV array substrate, and further attaching the stacked molded die to a first side of a package using the first level interconnect.

In some embodiments, the package includes a second level interconnect on a second side of the package.

In some embodiments, the first flip chip die includes flip chip contacts on a first side of the first flip chip die, and in some embodiments attaching the first flip chip die includes flipping the first flip chip to attach the flip chip contacts with the TSV array substrate.

In some embodiments, attaching the wire bond dies in a stack to the first flip chip die includes attaching the wire bond dies using die backside films.

In some embodiments, the method further includes depositing material to enable wire bonding on the wire bond pads. In some embodiments, depositing material includes depositing TiAl (Titanium Aluminum).

What is claimed is:

1. An apparatus comprising:
a TSV array substrate including a plurality of through silicon vias (TSVs) and a plurality of wire bond contacts;
a stack of one or more wire bond dies; and
a package, a first side of the package being coupled with the TSV array substrate by a first interconnect;
wherein the one or more wire bond dies are connected via one or more wires to one or more wire bond contacts of the TSV array substrate; and
wherein the TSV array substrate provides connections for each of the one or more wire bond dies.

2. The apparatus of claim 1, further comprising:
at least a first flip chip die including flip chip contacts on a first side of the first die, the first flip chip die being flipped to couple the flip chip contacts with the TSV array substrate.

3. The apparatus of claim 2, wherein the stack of one or more wire bond dies is coupled to a second side of the flip chip die.

4. The apparatus of claim 1, wherein the TSV array substrate containing the wire bond pads includes deposited material to enable wire bonding on the wire bond pads.

5. The apparatus of claim 4, wherein the deposited material includes TiAl (Titanium Aluminum).

6. The apparatus of claim 1, further comprising a second interconnect on a second side of the package.

7. A mobile device comprising:
a processor;
a memory for storage of data for the processor; and
a transmitter and receiver for the transfer of data together with one or more antennae for data transmission and reception;
wherein one or more components of the mobile device are included in a die stack including:
a TSV array substrate including a plurality of through silicon vias (TSVs) and a plurality of wire bond contacts,
a stack of one or more wire bond dies, and
a package, a first side of the package being coupled with the TSV array substrate by a first interconnect;
wherein the one or, more wire bond dies are connected via one or more wires to one or more wire bond contacts of the TSV array substrate; and
wherein the TSV array substrate provides connections for each of the one or more wire bond dies.

8. The mobile device of claim 7, wherein the die stack further includes at least a first flip chip die including flip chip contacts on a first side of the first die, the first flip chip die being flipped to couple the flip chip contacts with the TSV array substrate.

9. The mobile device of claim 8, wherein the stack of one or more wire bond dies is coupled to a second side of the flip chip die.

10. The mobile device of claim 7, wherein the TSV array substrate containing the wire bond pads includes deposited material to enable wire bonding on the wire bond pads.

11. The mobile device of claim 10, wherein the deposited material includes TiAl (Titanium Aluminum).

12. The mobile device of claim 7, wherein the die stack further includes a second interconnect on a second side of the package.

13. A method comprising:
fabricating a TSV array wafer including a plurality of through silicon vias (TSVs);
attaching a first flip chip die to a first side of the TSV array wafer using a chip to wafer attachment; and
attaching a plurality of wire bond dies in a stack to the first flip chip die, and wire bonding the wire bond dies on wire bond pads to the TSV array wafer.

14. The method of claim 13, further comprising:
enclosing the dies in a mold and singulating a stacked molded die including the first flip-chip, the plurality of wire bond dies, and a TSV array substrate.

15. The method of claim 14, wherein the TSV array substrate includes a first level interconnect on a second side of the TSV array substrate, and further comprising:
attaching the stacked molded die to a first side of a package using the first level interconnect.

16. The method of claim 15, wherein the package includes a second level interconnect on a second side of the package.

17. The method of claim 13, wherein the first flip chip die includes flip chip contacts on a first side of the first flip chip die, and wherein attaching the first flip chip die includes flipping the first flip chip to attach the flip chip contacts with the TSV array substrate.

18. The method of claim 17, wherein attaching the plurality of wire bond dies in a stack to the first flip chip die includes attaching the wire bond dies using die backside films.

19. The method of claim 13, further comprising:
depositing material to enable wire bonding on the wire bond pads.

20. The method of claim 19, wherein depositing material includes depositing TiAl (Titanium Aluminum).
